(19) United States
(12) Patent Application Publication
(10) Pub. No.: US 2024/0324208 A1
(43) Pub. Date: Sep. 26, 2024

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Daichi KAWASAKI, Yokkaichi Mie (JP)

(73) Assignee: Kioxia Corporation, Tokyo (JP)

(21) Appl. No.: 18/591,272

(22) Filed: Feb. 29, 2024

(30) Foreign Application Priority Data
Mar. 22, 2023 (JP) 2023-045465

(51) Int. Cl. H10B 43/27

(52) U.S. Cl. CPC H10B 43/27

(57) ABSTRACT

A semiconductor storage device includes a stacked body including conductive layers and insulating layers alternately stacked; a first region extending in a first lateral direction and has a width in a second lateral direction; first pillars disposed in a second region on a first side of the first region, and each extending in the stacked body; second pillars disposed in a third region on a second side of the first region, and each extending in the stacked body; a plate-shaped portion disposed in the first region, extending in the first lateral direction, and dividing the stacked body in the second lateral direction; and a semiconductor layer disposed in the first region adjacent to the plate-shaped portion in the second lateral direction, wherein the semiconductor layer has an upper end portion around upper end portions of the first and second pillars, and a lower end portion above an uppermost conductive layer.

### CROSS-REFERENCE TO RELATED APPLICATION

This application is based upon and claims the benefit of priority from Japanese Patent Application No. 2023-045465, filed Mar. 22, 2023, the entire contents of which are incorporated herein by reference.

### FIELD

Embodiments described herein relate generally to a semiconductor storage device and a method for manufacturing a semiconductor storage device.

### BACKGROUND

In a semiconductor storage device such as a three-dimensional nonvolatile memory, a plurality of pillars at which memory cells are formed are disposed in a periodic pattern in a stacked body in which a plurality of conductive layers are stacked. When memory holes that serve as a plurality of pillars are formed by penetrating a stacked body, the periodicity of the disposition of the memory holes may be impaired because another configuration is disposed. Meanwhile, in a region where the periodicity of the disposition of the memory holes is impaired, the processing accuracy of the memory holes may be reduced.

### DESCRIPTION OF THE DRAWINGS

FIG. 1 is a sectional view showing a schematic configuration example of a semiconductor storage device according to an embodiment.

FIGS. 2A and 2B are views showing an example of a configuration of a semiconductor storage device according to the embodiment.

FIG. 3 is a view sequentially illustrating a part of the procedure of a method for manufacturing a semiconductor storage device according to the embodiment.

FIG. 4 is a view sequentially illustrating a part of the procedure of the method for manufacturing a semiconductor storage device according to the embodiment.

FIG. 5 is a view sequentially illustrating a part of the procedure of the method for manufacturing a semiconductor storage device according to the embodiment.

FIG. 6 is a view sequentially illustrating a part of the procedure of the method for manufacturing a semiconductor storage device according to the embodiment.

FIG. 7 is a view sequentially illustrating a part of the procedure of the method for manufacturing a semiconductor storage device according to the embodiment.

FIG. 8 is a view sequentially illustrating a part of the procedure of the method for manufacturing a semiconductor storage device according to the embodiment.

FIGS. 9A to 9E are views sequentially illustrating a part of the procedure of the method for manufacturing a semiconductor storage device according to the embodiment.

FIGS. 10A to 10F are views sequentially illustrating a part of the procedure of the method for manufacturing a semiconductor storage device according to the embodiment.

FIG. 11 is a view sequentially illustrating a part of the procedure of the method for manufacturing a semiconductor storage device according to the embodiment.

FIGS. 12A to 12F are views sequentially illustrating a part of the procedure of the method for manufacturing a semiconductor storage device according to the embodiment.

FIGS. 13A to 13C are views sequentially illustrating a part of the procedure of the method for manufacturing a semiconductor storage device according to the embodiment.

FIGS. 14A and 14B are partially enlarged sectional views showing a state in which a memory hole according to a comparative example is formed.

FIGS. 15A to 15F are XY sectional views showing examples of various stopper layers provided in the semiconductor storage device according to the embodiment and a modification example of the embodiment.

### DETAILED DESCRIPTION

Embodiments provide a semiconductor storage device and a method for manufacturing a semiconductor storage device, which can improve the processing accuracy of a memory hole.

In general, according to one embodiment, a semiconductor storage device includes a stacked body including a plurality of conductive layers and a plurality of insulating layers alternately stacked on top of one another; a first region that extends in a first lateral direction and has a width in a second lateral direction; a plurality of first pillars disposed in a second region on a first side of the first region in the second lateral direction, and each extend in the stacked body, wherein first memory cells are formed at intersections between the plurality of conductive layers and the plurality of first pillars, respectively; a plurality of second pillars that disposed in a third region on a second side of the first region in the second lateral direction, and each extend in the stacked body, and wherein second memory cells are formed at intersections between the plurality of conductive layers and the plurality of second pillars, respectively; a plate-shaped portion disposed in the first region, extending in the first lateral direction, and dividing the stacked body in the second lateral direction; and a semiconductor layer disposed in the first region adjacent to the plate-shaped portion in the second lateral direction, wherein the semiconductor layer has an upper end portion around upper end portions of the plurality of first and second pillars, and a lower end portion above an uppermost conductive layer of the plurality of conductive layers.

Hereinafter, embodiments of the present disclosure will be described in detail with reference to the drawings. Further, the present disclosure is not limited to the following embodiment. The elements in the following embodiments include those that can be easily assumed by those skilled in the art or those that are substantially the same.

### Configuration Example of Semiconductor Storage Device

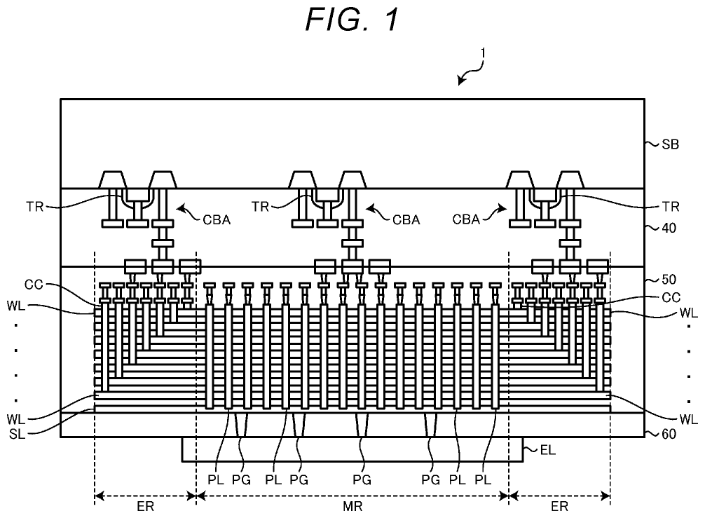

FIG. 1 is a sectional view showing a schematic configuration example of a semiconductor storage device 1 according to an embodiment. Meanwhile, in FIG. 1, hatching is omitted in consideration of the visibility of the drawing.

As shown in FIG. 1, the semiconductor storage device 1 includes an electrode film EL, a source line SL, and a plurality of word lines WL in order from the lower side of the paper surface. In addition, the semiconductor storage device 1 includes a peripheral circuit CBA provided on the semiconductor substrate SB above the plurality of word lines WL.

The source line SL is disposed on the electrode film EL through the insulating layer 60. A plurality of the plugs PG are disposed in the insulating layer 60, and the source line SL and the electrode film EL maintain electrical conduction through the plugs PG. Accordingly, it is possible to supply power to the semiconductor storage device 1 from a power supply circuit (not illustrated) provided in the semiconductor storage device 1 through the electrode film EL and the plug PG.

A plurality of word lines WL are stacked on the source line SL. A memory region MR is disposed at a central portion of the plurality of word lines WL, and contact regions ER are disposed at both end portions of the plurality of word lines WL.

A plurality of pillars PL penetrating the word line WL in the stacking direction are disposed in the memory region MR. A plurality of memory cells are formed at intersection portions between the pillar PL and the word line WL. Accordingly, the semiconductor storage device 1 is configured as, for example, a three-dimensional nonvolatile memory in which memory cells are disposed three-dimensionally in the memory region MR.

A plurality of contacts CC respectively connected to the plurality of word lines WL are disposed in the contact region ER.

From the contact CC, write voltage, read voltage, and the like are applied to the memory cells provided in the memory region MR at the central portion of the plurality of word lines WL through the word lines WL having the same height position as the memory cells. As described above, the word lines WL that are stacked in multiple layers are individually drawn out by these contacts CC.

The plurality of word lines WL, pillars PL, and contacts CC are covered with the insulating layer 50. The insulating layer 50 also extends around the plurality of word lines WL.

The semiconductor substrate SB above the insulating layer 50 is, for example, a silicon substrate or the like. A peripheral circuit CBA including a transistor TR, wiring, and the like is disposed on a surface of the semiconductor substrate SB. Various voltages applied from the contacts CC to the memory cell are controlled by the peripheral circuit CBA electrically connected to the contacts CC. In this way, the peripheral circuit CBA controls the electrical operation of the memory cell.

The peripheral circuit CBA is covered with the insulating layer 40, and the insulating layer 40 and the insulating layer 50, which covers the plurality of word lines WL, are bonded to each other, whereby the semiconductor storage device 1 including the configuration of the plurality of word lines WL, pillars PL, contacts CC, and the like and the peripheral circuit CBA is configured.

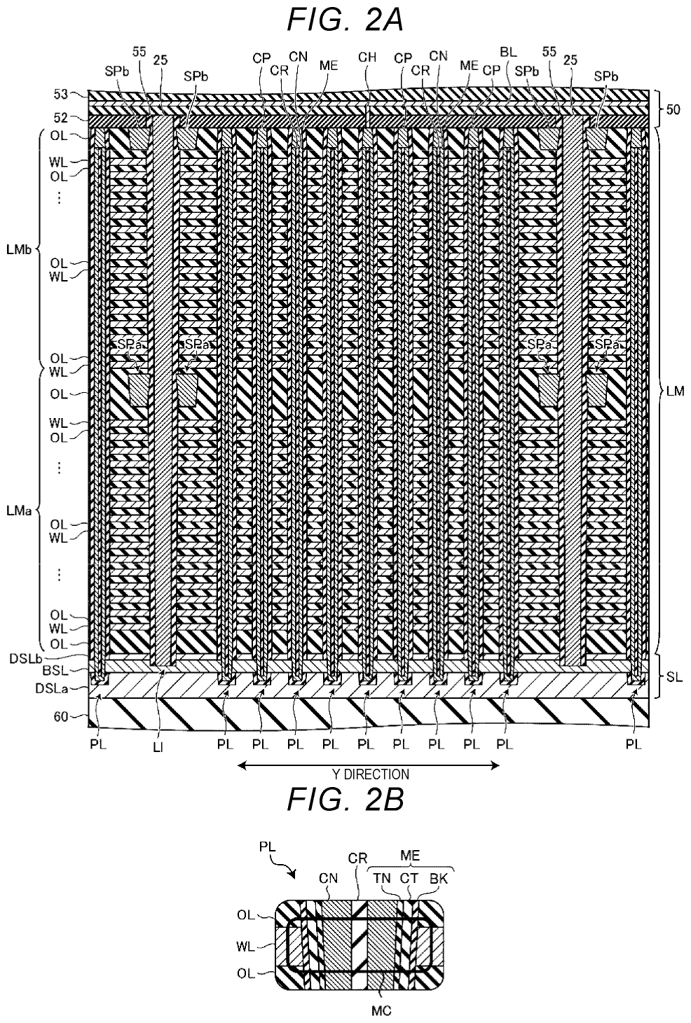

Next, a detailed configuration example of the semiconductor storage device 1 will be described with reference to FIGS. 2A and 2B. FIGS. 2A and 2B are views showing an example of a configuration of a semiconductor storage device 1 according to the embodiment.

More specifically, FIG. 2A is a sectional view along the Y direction showing an example of the configuration of the memory region MR. Meanwhile, in FIG. 2A, the structure below the insulating layer 60 and above the insulating layer 50 is not shown. FIG. 2B is an enlarged sectional view at a height position of the word line WL of the pillar PL disposed in the memory region MR.

In addition, in the present specification, both the X direction and the Y direction are directions along the direction of the plane of the word line WL, and the X direction and the Y direction are orthogonal to each other. In FIG. 2A, an Y direction is a left-right direction of the paper surface, and a X direction (not shown) is a direction perpendicular to the paper surface.

In addition, in the present specification, the electrical leading direction of the word line WL may be referred to as a first direction, and the first direction is a direction along the X direction. In addition, a direction intersecting the first direction may be referred to as a second direction, and the second direction is a direction along the Y direction. Meanwhile, since the semiconductor storage device 1 may include a manufacturing error, the first direction and the second direction are not necessarily orthogonal to each other.

In addition, in the present specification, the direction in which the word lines WL of the stacked body LM are stacked is referred to as the upper side. The direction in which the word lines WL are stacked may be determined by, for example, the shape of the pillar PL. For example, the lower end portion of the pillar PL may be disposed on the lower side in the direction in which the word lines WL are stacked, and may have a diameter smaller than that of the upper end portion, as will be described later. In addition, for example, the lower end portion of the pillar PL may be a closed end in which the multilayer structure of the pillar PL is closed, and the upper end portion of the pillar PL may be an open end in which the multilayer structure is opened.

As shown in FIG. 2A, the source line SL has a multilayer structure in which, for example, a lower source line DSLa, an intermediate source line BSL, and an upper source line DSLb are stacked in this order on the insulating layer 60.

The lower source line DSLa, the intermediate source line BSL, and the upper source line DSLb are, for example, a polysilicon layer or the like. Among the above, at least the intermediate source line BSL may be a conductive polysilicon layer or the like in which impurities are diffused.

The stacked body LM is disposed on the source line SL. The stacked body LM includes stacked bodies LMa and LMb in which a plurality of word lines WL and a plurality of insulating layers OL are alternately stacked one by one. The stacked body LMa as the first stacked body is disposed above the source line SL, and the stacked body LMb as the second stacked body is disposed on the stacked body LMa.

One or more select gate lines may be disposed through the insulating layer OL on a further lower layer of the word line WL of the lowermost layer of the stacked body LMa. In addition, one or more select gate lines may be disposed through the insulating layer OL on a further upper layer of the word line WL of the uppermost layer of the stacked body LMb.

Meanwhile, the number of layers of the word lines WL and the select gate lines stacked in the stacked body LM is predetermined.

The word line WL and the select gate line as the plurality of first and second conductive layers are, for example, a tungsten layer, a molybdenum layer, or the like. The insulating layers OL as the plurality of first and second insulating layers are, for example, a silicon oxide layer.

The uppermost insulating layers OL of each of the stacked bodies LMa and LMb and the lowermost insulating layer OL of the stacked body LMa are thicker than, for example, the other insulating layers OL in the stacked bodies LMa and LMb. The lowermost insulating layer OL of the stacked body LMa is disposed, for example, on the insulating layer 60, and the uppermost insulating layer OL of the stacked body LMa is in contact with the word line WL of the lowermost layer of the stacked body LMb. The insulating layers 52 and 53 are disposed in this order on the uppermost insulating layer OL of the stacked body LMb. The insulating layers 52 and 53 form a part of the insulating layer 50 described above, and the upper surface of the insulating layer 53 is in contact with the lower surface of the insulating layer 40 on the peripheral circuit CBA side.

The stacked body LM is divided in the Y direction by a plurality of plate-shaped contacts LI.

That is, each of the plate-shaped contacts LI as the plate-shaped portion is arranged in the Y direction, and extends in the direction along the stacking direction of the stacked body LM and the X direction. As described above, the plate-shaped contact LI continuously extends in the stacked body LM from one end portion to the other end portion of the stacked body LM in the X direction. In addition, the plate-shaped contact LI penetrates the stacked body LM and the upper source line DSLb and reaches the intermediate source line BSL.

In addition, each of the plate-shaped contacts LI includes the insulating layer 55 and the conductive layer 25. The insulating layer 55 is, for example, a silicon oxide layer or the like. The conductive layer 25 is, for example, a tungsten layer or a conductive polysilicon layer.

The insulating layers 55 cover the side wall of the plate-shaped contact LI facing the Y direction. The conductive layer 25 fills the insulating layer 55 and is electrically connected to the source line SL including the intermediate source line BSL. In addition, the conductive layer 25 is connected to the upper layer wiring in a cross section different from that in FIG. 2A. With such a configuration, the plate-shaped contact LI functions as a source line contact.

Meanwhile, instead of the plate-shaped contact LI, a plate-shaped member filled with an insulating layer may penetrate the stacked body LM and extend in the direction along the X direction, so that the stacked body LM may be divided in the Y direction. In this case, such a plate-shaped member does not have a function as a source line contact.

In the memory region MR of the stacked body LM, a plurality of pillars PL are dispersedly disposed, the plurality of pillars PL penetrating the stacked body LM, the upper source line DSLb, and the intermediate source line BSL and reaching the lower source line DSLa. More specifically, a plurality of pillars PL are dispersedly disposed in regions between the plate-shaped contacts LI adjacent to each other in the Y direction, respectively. The pillars PL are disposed to be separated from the plate-shaped contact LI by a predetermined distance in the Y direction.

Here, the disposition regions of the pillars PL on both sides of the single plate-shaped contact LI in the Y direction are examples of the second and third regions, respectively. In addition, a region in which the plate-shaped contact LI is disposed without providing the pillar PL and which has a predetermined width in the Y direction and extends in the direction along the X direction is an example of the first region.

The plurality of pillars PL are periodically arranged in a staggered shape, for example, as viewed from the stacking direction of the stacked body LM. Each of the pillars PL has a shape such as a circular shape, an elliptical shape, or an oval shape as a cross-sectional shape in a direction along the stacking direction of the stacked body LM, that is, a direction along the XY plane.

The pillars PL each have a tapered shape in which the diameter and the cross-sectional area are reduced from the upper layer side toward the lower layer side in a portion extending in the stacked body LMa in the stacking direction and a portion extending in the stacked body LMb in the stacking direction. Alternatively, the pillars PL each have, for example, a bowing shape in which the diameter and the cross-sectional area are maximized at a predetermined position between the upper layer side and the lower layer side in a portion penetrating the stacked body LMa and a portion penetrating the stacked body LMb.

Each of the plurality of pillars PL has a cap layer CP at an upper end portion of the pillar PL, a memory layer ME extending in the stacked body LM in the stacking direction, a channel layer CN that penetrates the stacked body LM and that is connected to the intermediate source line BSL, and a core layer CR serving as a core material of the pillar PL.

The memory layer ME is disposed on the side surface of the pillar PL excluding the depth position of the intermediate source line BSL. In addition, the memory layer ME is also disposed on the bottom surface of the pillar PL reaching the depth of the lower source line DSLa.

The channel layer CN reaches a depth of the lower source line DSLa by penetrating the stacked body LM, the upper source line DSLb, and the intermediate source line BSL inside the memory layer ME. That is, the channel layer CN is disposed on the side surface and the bottom surface of the pillar PL through the memory layer ME. The core layer CR further fills the channel layer CN.

Meanwhile, a part of the channel layer CN is in contact with the intermediate source line BSL on the side surface, and thus is electrically connected to the source line SL including the intermediate source line BSL. In addition, the cap layer CP is disposed at the upper end portion of the channel layer CN. The cap layer CP is disposed in the uppermost insulating layer OL of the stacked body LMb, and the upper surface of the cap layer CP is located at the height of the upper surface of the insulating layer OL. The cap layer CP is connected to the bit line BL extending in the insulating layer 53 in the direction along the Y direction through the plug CH disposed in the insulating layers 52 and 53.

As shown in FIG. 2B, the memory layer ME has a multilayer structure in which the block insulating layer BK, the charge storage layer CT, and the tunnel insulating layer TN are stacked in this order from the outer peripheral side of the pillar PL.

The block insulating layer BK and the tunnel insulating layer TN of the memory layer ME, and the core layer CR are, for example, a silicon oxide layer or the like. The charge storage layer CT of the memory layer ME is, for example, a silicon nitride layer. The channel layer CN and the cap layer CP are, for example, a semiconductor layer such as a polysilicon layer or an amorphous silicon layer.

With the above configuration, the memory cells MC are formed in the portions facing the individual word lines WL on the side surface of the pillar PL, respectively. A predetermined voltage is applied from the word line WL to write and read data to and from the memory cell MC.

The data from the memory cell MC is read to the bit line BL connected to the pillar PL. The bit line BL is further electrically connected to the peripheral circuit CBA through an upper layer wiring or the like. Accordingly, the data of the memory cell MC read out to the bit line BL is processed by the peripheral circuit CBA.

In addition, in a case where the stacked body LM has a select gate line in addition to the word line WL, with the above configuration, select gates are formed in portions facing the individual select gate lines on the side surface of the pillar PL, respectively. The select gates are turned on or off by applying a predetermined voltage from the select gate line, and the memory cell MC formed in the pillar PL to which these select gates belong is in a selected state or a non-selected state.

In addition, in a region in which the plate-shaped contact LI is disposed without disposing the pillar PL and which has a predetermined width in the Y direction and extends in the direction along the X direction, the stopper layers SPa and SPb as the plurality of first and second semiconductor layers are disposed in the uppermost insulating layers OL of the stacked bodies LMa and LMb, respectively.

Each of the stopper layers SPa and SPb is, for example, a polysilicon layer or the like. Meanwhile, the stopper layers SPa and SPb may be other semiconductor layers such as an amorphous silicon layer. The stopper layers SPa and SPb extend, for example, along the plate-shaped contact LI in a direction along the X direction on both sides of the plate-shaped contact LI in the Y direction.

In addition, among the stopper layers SPa and SPb, the height position of the upper end portion of the stopper layer SPb disposed in the uppermost insulating layer OL of the stacked body LMb is substantially the same as the height position of the upper end portion of the pillar PL described above. Meanwhile, the lower end portions of the stopper layers SPa and SPb are located above the word lines WL of the uppermost layer in the stacked bodies LMa and LMb in which the insulating layer OL is the uppermost layer, respectively. That is, the lower end portions of the stopper layers SPa and SPb do not reach the word lines WL immediately below the uppermost insulating layer OL in which the stopper layers SPa and SPb are disposed.

The stopper layers SPa and SPb are configured as dummies that do not contribute to the function of the semiconductor storage device 1, as will be described later. By disposing the stopper layers SPa and SPb as described above, the dummy stopper layers SPa and SPb, which are the semiconductor layers or the like, are prevented from being conductive with the word lines WL or the like.

The plate-shaped contact LI described above may have a reduced width in the Y direction at at least one of a position interposed between the stopper layers SPa on both sides in the Y direction and a position interposed between the stopper layers SPb on both sides in the Y direction. That is, the width of the plate-shaped contact LI in the Y direction may be narrower than other portions at the height position of at least any of the stopper layers SPa and SPb.

### Method for Manufacturing Semiconductor Storage Device

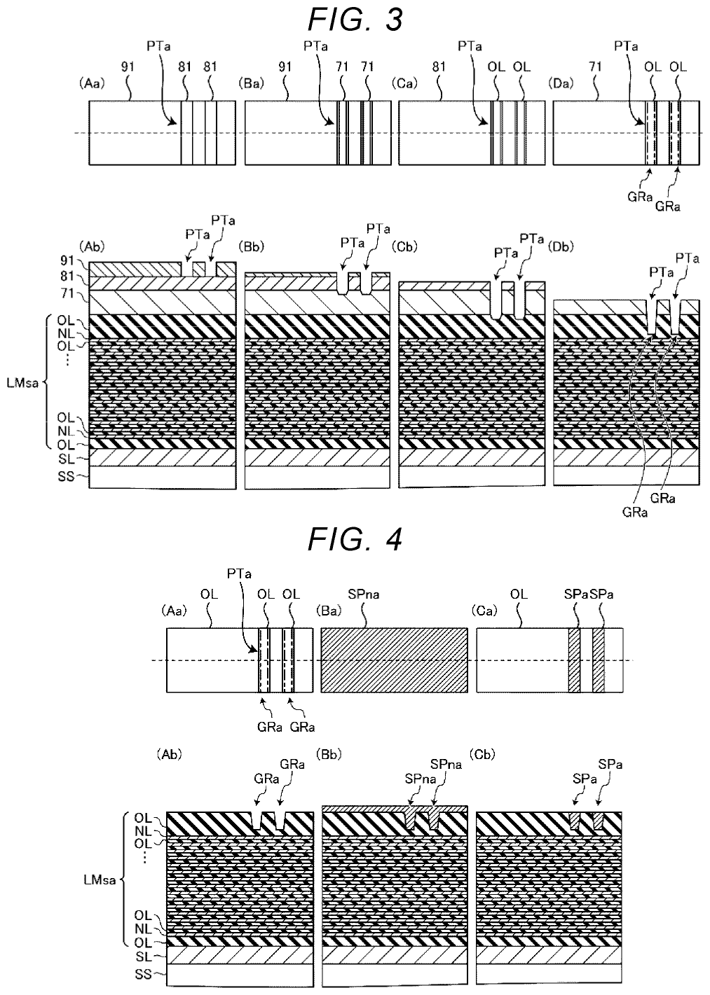

Next, a method for manufacturing a semiconductor storage device 1 according to the embodiment will be described with reference to FIGS. 3 to 13C. FIGS. 3 to 13C are views sequentially illustrating a part of a procedure of a method for manufacturing a semiconductor storage device 1 according to the embodiment.

First, FIGS. 3 and 4 show a state in which a stacked body LMsa, which is a lower layer portion of the stacked body LM before the word line WL is formed, and a stopper layer SPa are formed. FIG. 3 (Aa) to FIG. 3 (Da) and FIG. 4 (Aa) to FIG. 4 (Ca) are top views including a region in which a plate-shaped contact LI is to be formed later. FIG. 3 (Ab) to FIG. 3 (Db) and FIG. 4 (Ab) to FIG. 4 (Cb) are sectional views along Y direction including a region in which a plate-shaped contact LI is to be formed later.

As shown in FIG. 3 (Aa) and FIG. 3 (Ab), the source line SL is formed above the supporting substrate SS. The supporting substrate SS may be, for example, a semiconductor substrate such as a silicon substrate, an insulating substrate such as a ceramic substrate or a quartz substrate, a conductive substrate such as a sapphire substrate, or the like.

In addition, a stacked body LMsa in which a plurality of insulating layers NL and a plurality of insulating layers OL are alternately stacked one by one is formed on the source line SL. The insulating layer NL is, for example, a silicon nitride layer, and functions as a sacrificial layer to be replaced with a conductive material that is to be the word line WL later. The stacked body LMsa is a portion that is to be the stacked body LMa later via such a replacement processing.

In addition, the CVD-carbon layer 71, the dielectric anti-reflective coating (DARC) layer 81, and the photoresist layer 91 are formed on the stacked body LMsa in this order.

The photoresist layer 91 is an organic layer formed by, for example, a spin coating method, has a predetermined pattern formed by exposure and development, and is used as a mask pattern. In FIG. 3 (Aa) and FIG. 3 (Ba), the photoresist layer 91 has a plurality of groove patterns PTa extending in the direction along the X direction in a region in which the plate-shaped contact LI is to be formed later. The lower anti-reflective coating layer 81 is exposed from the bottom surface of the groove pattern Pta.

The anti-reflective coating layer 81 is an organic layer formed in the lower layer such as the photoresist layer 91 by, for example, a spin coating method or the like, and inhibits the reflection of light from the configuration located below the photoresist layer 91.

The CVD-carbon layer 71 is, for example, an organic layer formed by a chemical vapor deposition (CVD) method using a carbon-containing gas. The CVD-carbon layer 71 is used as a mask pattern, for example, by transferring a pattern of the photoresist layer 91.

The CVD-carbon layer 71 has a higher hardness than the photoresist layer 91 which is the same organic layer, and may be removed by ashing using oxygen plasma or the like.

As shown in FIG. 3 (Ba) and FIG. 3 (Bb), the groove pattern PTa of the photoresist layer 91 is transferred to the anti-reflective coating layer 81 by reactive ion etching (RIE). The lower CVD-carbon layer 71 is exposed from the bottom surface of the groove pattern PTa transferred to the anti-reflective coating layer 81.

As shown in FIG. 3 (Ca) and FIG. 3 (Cb), the groove pattern PTa of the anti-reflective coating layer 81 is transferred to the CVD-carbon layer 71 by RIE or the like. The uppermost insulating layer OL of the stacked body LMsa is exposed from the bottom surface of the groove pattern Pta transferred to the CVD-carbon layer 71. At this time, the photoresist layer 91 may be etched and removed to disappear.

As shown in FIG. 3 (Da) and FIG. 3 (Db), the uppermost insulating layer OL of the stacked body LMsa is processed by RIE or the like using the CVD-carbon layer 71 as a mask. As a result, the plurality of grooves GRa that reach the predetermined depth of the insulating layer OL and extend in the direction along the X direction are formed in the uppermost insulating layer OL of the stacked body LMsa. At this time, the anti-reflective coating layer 81 may be etched and removed to disappear.

As shown in FIG. 4 (Aa) and FIG. 4 (Ab), the CVD-carbon layer 71 is removed by ashing using oxygen plasma or the like.

As shown in FIG. 4 (Ba) and FIG. 4 (Bb), a semiconductor layer SPna such as a polysilicon layer covering the upper surface of the stacked body LMsa is formed. The semiconductor layer SPna also fills the groove GRa formed in the uppermost insulating layer OL of the stacked body LMsa.

As shown in FIG. 4 (Ca) and FIG. 4 (Cb), the semiconductor layer SPna on the upper surface of the stacked body LMsa is removed by chemical mechanical polishing (CMP) or the like to form a plurality of stopper layers SPa in which the semiconductor layer SPna fills the grooves GRa.

In the examples of FIG. 4 (Ca) and FIG. 4 (Cb), the stopper layer SPa extending in the direction along the X direction and the stopper layer SPa extending in the direction along the Y direction are formed to be separated by a predetermined distance in the Y direction.

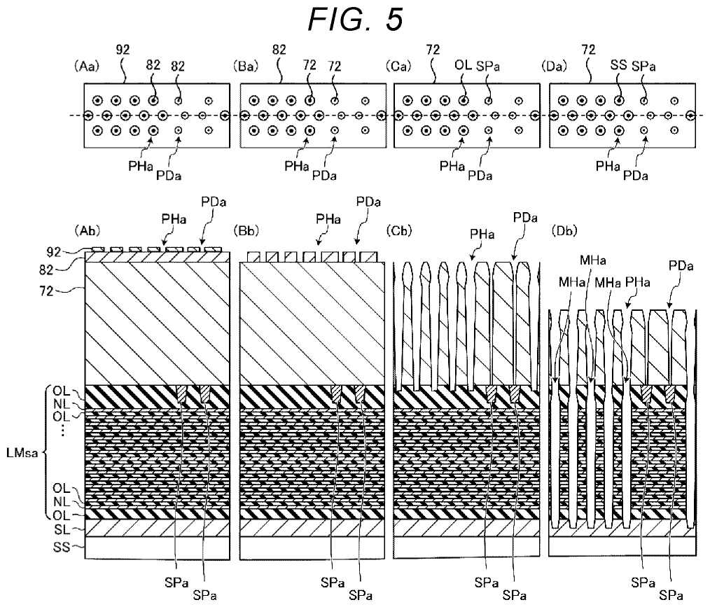

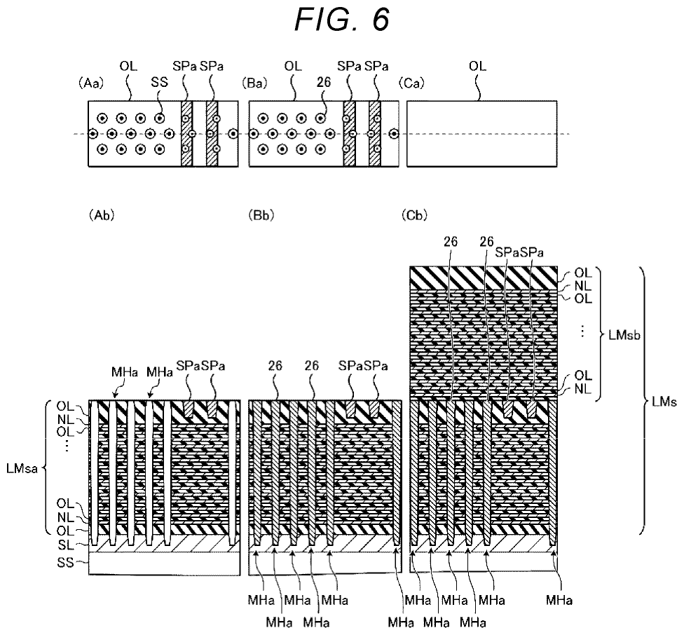

Next, FIGS. 5 and 6 show a state in which the memory hole MHa serving as a lower structure of the pillar PL is formed.

FIG. 5 (Aa) to FIG. 5 (Da) and FIG. 6 (Aa) to FIG. 6 (Ca) are top views including a region in which a plate-shaped contact LI is to be formed later, similarly to FIG. 3 (Aa) to FIG. 3 (Da) and FIG. 4 (Aa) to FIG. 4 (Ca) described above. FIG. 5 (Ab) to FIG. 5 (Db) and FIG. 6 (Ab) to FIG. 6 (Cb) are sectional views along the Y direction including a region in which a plate-shaped contact LI is to be formed later, similarly to FIG. 3 (Ab) to FIG. 3 (Db) and FIG. 4 (Ab) to FIG. 4 (Cb) described above.

As shown in FIG. 5 (Aa) and FIG. 5 (Ab), the CVD-carbon layer 72, the anti-reflective coating layer 82, and the photoresist layer 92 are formed on the stacked body LMsa in this order. The photoresist layer 92 has a plurality of hole patterns PHa and PDa which are dispersedly disposed over the entirety of a region in which the plate-shaped contact LI is to be formed later and a region, which is adjacent to the region in the Y direction and is to be the memory region MR later. The hole patterns PHa and PDa have a periodic pattern.

The hole pattern PHa is disposed in a region that is to be the memory region MR later at a predetermined pitch. The pitch and the disposition position of the hole pattern PHa substantially coincide with, for example, the pitch and the disposition position of the pillar PL described above.

The hole pattern PDa is disposed in a region in which the plate-shaped contact LI is to be formed later at a predetermined pitch. The hole pattern PDa is preferably formed to have a smaller diameter and opening area than the hole pattern PHa. As an example, the opening area of the hole pattern PDa may be 40% or more and 90% or less, and more preferably 50% or more and 80% or less with respect to the opening area of the hole pattern PHa. The pitch of the hole pattern PDa may substantially coincide with the pitch of the hole pattern PHa. Meanwhile, the pitch of the hole pattern PDa may not coincide with the pitch of the hole pattern PHa.

As shown in FIG. 5 (Ba) and FIG. 5 (Bb), the hole patterns PHa and PDa of the photoresist layer 92 are transferred to the anti-reflective coating layer 82 by RIE or the like. The lower CVD-carbon layer 72 is exposed from the bottom surfaces of the hole patterns PHa and PDa transferred to the anti-reflective coating layer 82.

As shown in FIG. 5 (Ca) and FIG. 5 (Cb), the hole patterns PHa and PDa of the anti-reflective coating layer 82 are transferred to the CVD-carbon layer 72 by RIE or the like. The uppermost insulating layer OL of the stacked body LMsa is exposed the bottom surface of the hole pattern PHa transferred to the CVD-carbon layer 72, and the stopper layer SPa formed in the uppermost insulating layer OL is exposed from the bottom surface of the hole pattern PDa. At this time, the photoresist layer 92 and the anti-reflective coating layer 82 may be etched and removed to disappear.

As shown in FIG. 5 (Da) and FIG. 5 (Db), the stacked body LMsa is processed by RIE or the like using the CVD-carbon layer 72 as a mask. As a result, the plurality of memory holes MHa that penetrate the stacked body LMsa and reach a predetermined depth of the source line SL are formed in a region that is to be the memory region MR later. The upper surface of the supporting substrate SS is exposed on the bottom surface of the plurality of memory holes MHa.

Meanwhile, in the region where the plate-shaped contact LI is to be formed later, the etching of the stacked body LMsa is hindered by the stopper layer SPa, and thus the transfer of the hole pattern PDa to the stacked body LMsa is prevented. As described above, in a case where the hole pattern PDa has a smaller diameter and opening area than the hole pattern PHa, the etching of the stacked body LMsa in the region where the plate-shaped contact LI is to be formed later is further hindered, and thus the stacked body LMsa can be more reliably protected by the stopper layer SPa.

As shown in FIG. 6 (Aa) and FIG. 6 (Ab), the CVD-carbon layer 72 is removed by ashing using oxygen plasma or the like.

As shown in FIG. 6 (Ba) and FIG. 6 (Bb), the sacrificial layer 26 such as a carbon layer fills the plurality of memory holes MH. The sacrificial layer 26 is a temporary structure that is removed later by wet etching, ashing, or the like. The carbon layer used as the sacrificial layer 26 is an organic layer, and is formed by a CVD method or the like in the same manner as the CVD-carbon layers 71 and 72 described above, or by a spin coating method or the like.

As shown in FIG. 6 (Ca) and FIG. 6 (Cb), a stacked body LMsb in which insulating layers NL as a plurality of first insulating layers and insulating layers OL as a plurality of second insulating layers are alternately stacked one by one is formed on the stacked body LMsa. The stacked body LMsb is a portion in which the insulating layer NL is later replaced with the word line WL to be the stacked body LMb. As a result, a stacked body LMs having the stacked bodies LMsa and LMsb is formed.

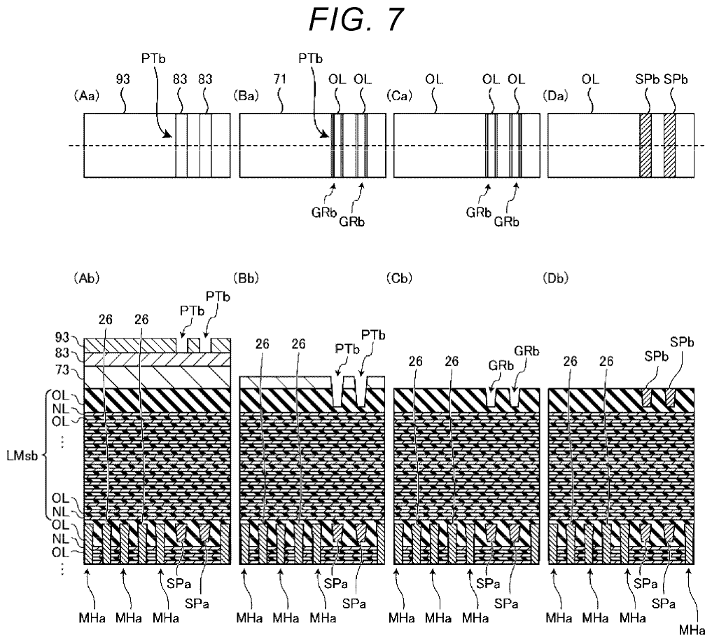

Next, FIG. 7 shows a state in which the stopper layer SPb is formed in the stacked body LMsb. FIG. 7 (Aa) to FIG. 7 (Da) are top views including a region in which a plate-shaped contact LI is to be formed later, similarly to FIG. 6 (Aa) to FIG. 6 (Ca), and the like described above. FIG. 7 (Ab) to FIG. 7 (Db) are sectional views along Y direction including a region in which a plate-shaped contact LI is to be formed later, similarly to FIG. 6 (Ab) to FIG. 6 (Cb), and the like described above.

Meanwhile, in FIG. 7, a part of the configuration including the stacked body LMsa below the stacked body LMsb is not shown.

As shown in FIG. 7 (Aa) and FIG. 7 (Ab), the CVD-carbon layer 73, the anti-reflective coating layer 83, and the photoresist layer 93 are formed on the stacked body LMsb in this order. The photoresist layer 93 has a plurality of groove patterns PTb extending in the direction along the X direction in a region in which the plate-shaped contact LI is to be formed later.

As shown in FIG. 7 (Ba) and FIG. 7 (Bb), the groove pattern PTb of the photoresist layer 93 is subsequently transferred to the anti-reflective coating layer 83 and the CVD-carbon layer 73 by RIE or the like. In addition, the uppermost insulating layer OL of the stacked body LMsb is processed by RIE or the like using the CVD-carbon layer 73 to which the groove pattern PTb is transferred as a mask. As a result, the plurality of grooves GRb that reach the predetermined depth of the insulating layer OL and extend in the direction along the X direction are formed in the uppermost insulating layer OL of the stacked body LMsb.

As shown in FIG. 7(Ca) and FIG. 7 (Cb), the CVD-carbon layer 73 is removed by ashing using oxygen plasma or the like.

As shown in FIG. 7 (Da) and FIG. 7 (Db), the semiconductor layer such as the polysilicon layer that covers the upper surface of the stacked body LMsb and that fills the groove GRb is formed, and the semiconductor layer on the upper surface of the stacked body LMsb is removed by CMP or the like. As a result, the stopper layer SPb in which the semiconductor layer fills the groove GPb is formed in the uppermost insulating layer OL of the stacked body LMsb. The upper surface of the stopper layer SPb is located at a height substantially equal to the upper surface of the uppermost insulating layer OL of the stacked body LMsb.

In the examples of FIG. 7 (Da) and FIG. 7 (Db), the stopper layer SPb as a third semiconductor layer extending in the direction along the X direction and the stopper layer SPb as a fourth semiconductor layer extending in the direction along the Y direction are formed to be separated by a predetermined distance in the Y direction.

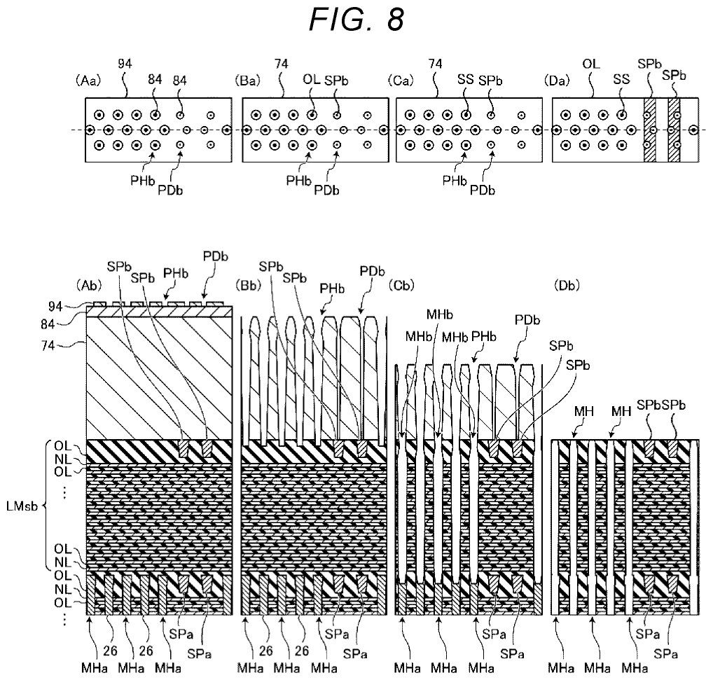

Next, FIG. 8 shows a state in which the memory hole MHb serving as an upper structure of the pillar PL is formed.

FIG. 8 (Aa) to FIG. 8 (Da) are top views including a region in which a plate-shaped contact LI is to be formed later, similarly to FIG. 7 (Aa) to FIG. 7 (Da), and the like described above. FIG. 8 (Ab) to FIG. 8 (Db) are sectional views along Y direction including a region in which a plate-shaped contact LI is to be formed later, similarly to FIG. 7 (Ab) to FIG. 7 (Db), and the like described above.

Even in FIG. 8, a part of the configuration including the stacked body LMsa below the stacked body LMsb is not shown.

As shown in FIG. 8 (Aa) and FIG. 8 (Ab), the CVD-carbon layer 74, the anti-reflective coating layer 84, and the photoresist layer 94 are formed on the stacked body LMsb in this order. The photoresist layer 94 has a plurality of hole patterns PHb and PDb which are dispersedly disposed over the entirety of a region in which the plate-shaped contact LI is to be formed later and a region, which is adjacent to the region in the Y direction and is to be the memory region MR later. The hole patterns PHb and PDb have a periodic pattern.

The hole pattern PHb as the first hole pattern is disposed at a predetermined pitch as the first pitch in a region that is to be the memory region MR later. The pitch and the disposition position of the hole pattern PHb substantially coincide with, for example, the pitch and the disposition position of the pillar PL described above. In addition, the plurality of hole patterns PHb are disposed at positions overlapping with the plurality of memory holes MHa formed in the stacked body LMsa in the stacking direction, respectively.

The hole pattern PDb as the second hole pattern is disposed in a region in which the plate-shaped contact LI is to be formed later at a predetermined pitch as the second pitch. The hole pattern PDb is preferably formed to have a smaller diameter and opening area than the hole pattern PHb. As an example, the opening area of the hole pattern PDb may be 40% or more and 90% or less, and more preferably 50% or more and 80% or less with respect to the opening area of the hole pattern PHb. The pitch of the hole pattern PDb may substantially coincide with the pitch of the hole pattern PHb. Meanwhile, the pitch of the hole pattern PDb may not coincide with the pitch of the hole pattern PHb.

As shown in FIG. 8 (Ba) and FIG. 8 (Bb), the hole patterns PHb and PDb of the photoresist layer 94 are subsequently transferred to the anti-reflective coating layer 84 and the CVD-carbon layer 74 by RIE or the like. In addition, the stacked body LMsb is processed by RIE or the like using the CVD-carbon layer 74 to which the hole patterns PHb and PDb are transferred as a mask.

Accordingly, a plurality of memory holes MHb that penetrate the stacked body LMsb and respectively reach the plurality of memory holes MHa formed in the stacked body LMSa are formed. The sacrificial layer 26 that fills the memory hole MHa is exposed on the bottom surfaces of the plurality of memory holes MHb.

Meanwhile, in the region where the plate-shaped contact LI is to be formed later, the etching of the stacked body LMsb is hindered by the stopper layer SPb, and thus the transfer of the hole pattern PDb to the stacked body LMsb is prevented. As described above, in a case where the hole pattern PDb has a smaller diameter and opening area than the hole pattern PHb, the etching of the stacked body LMsb in the region where the plate-shaped contact LI is to be formed later is further hindered, and thus the stacked body LMsb can be more reliably protected by the stopper layer SPb.

As shown in FIG. 8 (Da) and FIG. 8 (Db), the CVD-carbon layer 74 is removed by ashing using oxygen plasma or the like. At this time, the sacrificial layer 26, which fills the plurality of memory holes MHa and is for example, a carbon layer or the like, is also removed. As a result, the entire memory holes MHb and MHa communicate with each other, and a plurality of memory holes MH reaching the source line SL by penetrating the stacked bodies LMsb and LMsa are formed.

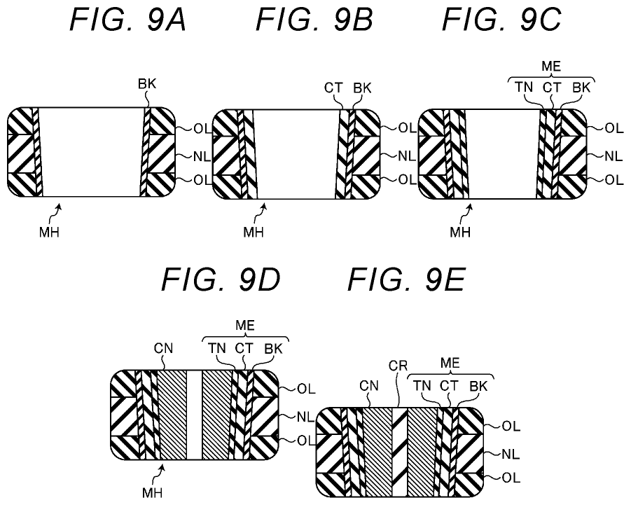

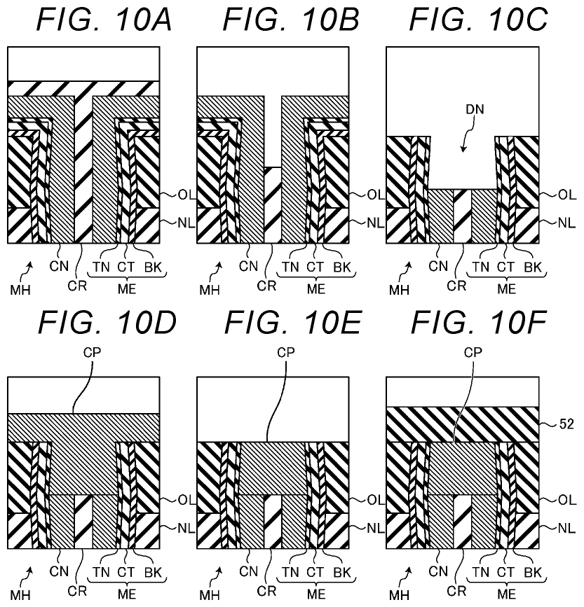

Next, FIGS. 9A to 10F show a state in which a multilayer structure is formed in the memory hole MH.

FIGS. 9A to 9E are enlarged sectional views of the memory hole MH at a certain height position of the insulating layer NL. FIGS. 10A and 10F are enlarged sectional views of the upper end portion of the memory hole MH.

As shown in FIG. 9A, a block insulating layer BK such as a silicon oxide layer is formed on the side wall of the memory hole MH. Although not shown, the block insulating layer BK is also formed on the upper surface of the stacked body LMsb and the bottom surface of the memory hole MH.

As shown in FIG. 9B, the charge storage layer CT such as a silicon nitride layer is formed on the side wall of the memory hole MH through the block insulating layer BK. Although not shown, the charge storage layer CT is also formed on the upper surface of the stacked body LMsb and the bottom surface of the memory hole MH through the block insulating layer BK.

As shown in FIG. 9C, a tunnel insulating layer TN such as a silicon oxide layer is formed on the side wall of the memory hole MH through the block insulating layer BK and the charge storage layer CT. As a result, the memory layer ME including the block insulating layer BK, the charge storage layer CT, and the tunnel insulating layer TN is formed on the side wall of the memory hole MH. Although not shown, the tunnel insulating layer TN is also formed on the upper surface of the stacked body LMsb and the bottom surface of the memory hole MH through the block insulating layer BK and the charge storage layer CT.

As shown in FIG. 9D, a channel layer CN which is a semiconductor layer such as an amorphous silicon layer or a polysilicon layer is formed on the side wall of the memory hole MH through the memory layer ME. Although not shown, the channel layer CN is also formed on the upper surface of the stacked body LMsb and the bottom surface of the memory hole MH through the memory layer ME.

As shown in FIG. 9E, the void surrounded by the channel layer CN of the memory hole MH is filled with the silicon oxide layer or the like to form the core layer CR. Although not shown, the core layer CR is also formed on the upper surface of the stacked body LMsb through the memory layer ME and the channel layer CN.

As shown in FIG. 10A, by the processing of FIGS. 9A to 9E, the memory layer ME, the channel layer CN, and the core layer CR are formed in this order on the upper surface of the stacked body LMsb including the opening of the memory hole MH.

As shown in FIG. 10B, the core layer CR on the upper surface of the stacked body LMsb is removed by etching back. At this time, the core layer CR at the upper end portion of the memory hole MH is caused to retreat in the memory hole MH in the depth direction by performing the surplus etching back.

As shown in FIG. 10C, the channel layer CN on the upper surface of the stacked body LMsb is removed by etching back. At this time, the channel layer CN at the upper end portion of the memory hole MH is caused to retreat in the memory hole MH in the depth direction by performing the surplus etching back. Accordingly, the recess DN is formed at the upper end portion of the memory hole MH.

As shown in FIG. 10D, a cap layer CP that covers the upper surface of the stacked body LMsb is formed. The cap layer CP fills the recess DN at the upper end portion of the memory hole MH.

As shown in FIG. 10E, the cap layer CP on the upper surface of the stacked body LMsb is removed by CMP or the like. As a result, the cap layer CP is formed, which is exposed on the upper surface of the stacked body LMsb and is located at the upper end portion of the memory hole MH.

At this time, the upper surface of the cap layer CP that is disposed at the upper end portion of the pillar PL is located at a height substantially equal to the upper surface of the uppermost insulating layer OL of the stacked body LMsb, as in the case of the upper surface of the stopper layer SPb. That is, the stopper layer SPb has the upper end portion at a height position substantially equal to the upper end portion of the pillar PL.

As shown in FIG. 10F, an insulating layer 52 that covers the upper surface of the stacked body LMsb is formed. As a result, the upper surface of the cap layer CP is covered with the insulating layer 52. Although not shown, the upper surface of the stopper layer SPb is also covered with the insulating layer 52 in the same manner.

Next, a state in which the slit ST that is to be the plate-shaped contact LI later is formed will be described with reference to FIG. 11.

FIG. 11 (Aa) to FIG. 11 (Da) are top views including a region in which a plate-shaped contact LI is to be formed later, similarly to FIG. 8 (Aa) to FIG. 8 (Da), and the like described above. FIG. 11 (Ab) to FIG. 11 (Db) are sectional views along Y direction including a region in which a plate-shaped contact LI is to be formed later, similarly to FIG. 8 (Ab) to FIG. 8 (Db), and the like described above.

As shown in FIG. 11 (Aa) and FIG. 11 (Ab), the above-described multilayer structure is formed in the memory hole MH penetrating the stacked bodies LMsa and LMsb.

The CVD-carbon layer 75, the anti-reflective coating layer 85, and the photoresist layer 95 are formed on the insulating layer 52 in this order. The photoresist layer 95 has a groove pattern PTs extending in the direction along the X direction in a region in which the plate-shaped contact LI is to be formed later.

As shown in FIG. 11 (Ba) and FIG. 11 (Bb), the groove pattern PTs of the photoresist layer 95 is subsequently transferred to the anti-reflective coating layer 85 and the CVD-carbon layer 75 by RIE or the like. In addition, the insulating layer 52 and the stacked bodies LMsa and LMsb are processed by RIE or the like using the CVD-carbon layer 75 to which the groove pattern PTs is transferred as a mask. Accordingly, the slit ST is formed, which reaches a predetermined depth of the source line SL by penetrating the insulating layer 52 and the stacked bodies LMsa and LMsb to extend in the direction along the X direction.

In addition, when the slit ST is formed by penetrating the insulating layer 52 and the stacked bodies LMsa and LMsb, the CVD-carbon layer 75 is also gradually etched and removed. Accordingly, the CVD-carbon layer 75 at the end portion of groove pattern PTs may gradually retreat to both sides in the Y direction, and the width of the groove pattern PTs in the Y direction may be widened. In addition, as the width of the groove pattern PTs is widened, the processing dimension of the upper end portion of the slit ST is also widened.

Therefore, the slit ST can be processed by RIE or the like under conditions that are selective with respect to the stopper layers SPb and SPa formed on both sides of the slit ST in the Y direction. As a result, the stopper layers SPb and SPa can function as a secondary mask for the slit ST processing, and the width of the slit ST in the Y direction, which is widened as the groove pattern PTs retreats, can be narrowed again.

In this case, the slit ST has a width in the Y direction wider than the design value at the upper end portion in the insulating layer 52, and has a shape in which the width in the Y direction is narrowed from the upper end portion at the height position of at least any one of the stopper layers SPb and SPa. Alternatively, the slit ST may have a shape in which the width in the Y direction is narrowed from the upper end portion over the entire region below at least any of the stopper layers SPb and SPa.

As shown in FIG. 11 (Da) and FIG. 11 (Db), the CVD-carbon layer 75 is removed by ashing using oxygen plasma or the like.

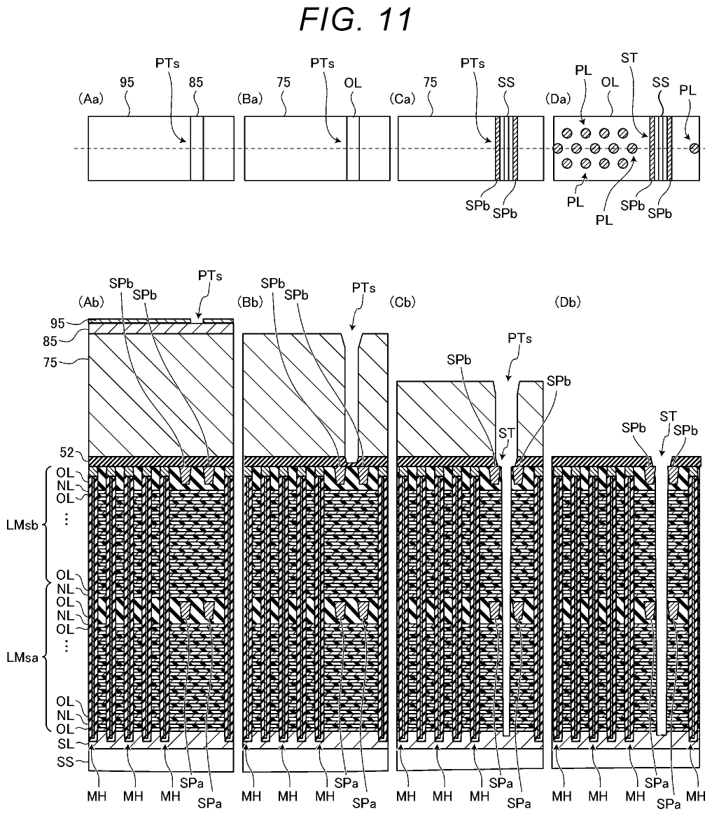

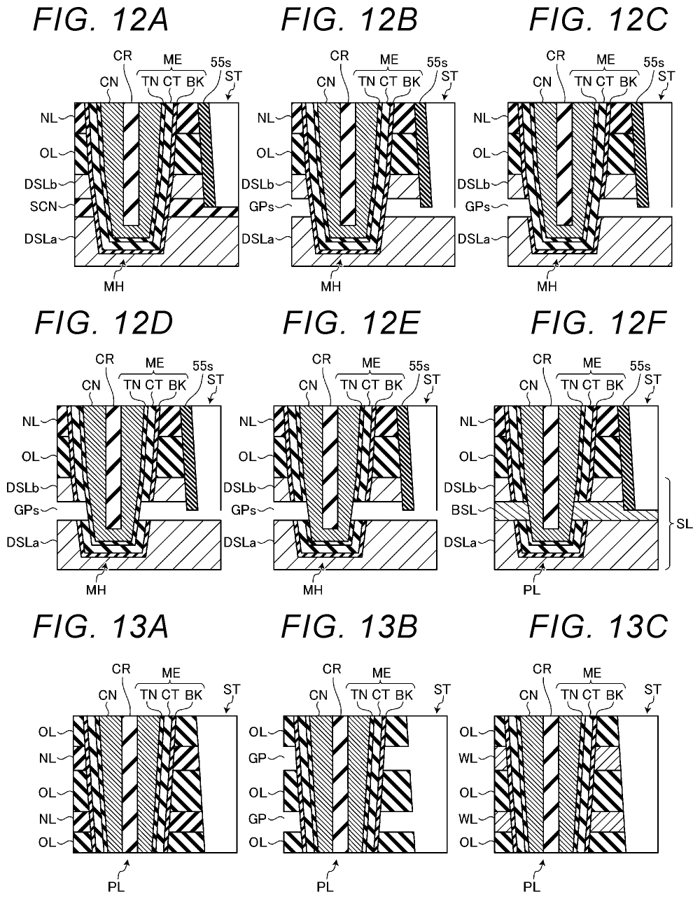

Next, a state in which the intermediate source line BSL is formed will be described with reference to FIGS. 12A to 12F. FIGS. 12A to 12F are enlarged sectional views of the lower end portion of the memory hole MH.

As shown in FIG. 12A, initially, when forming the source line SL, the intermediate sacrificial layer SCN is formed instead of the above-described intermediate source line BSL, the intermediate sacrificial layer SCN being interposed between the lower source line DSLa and the upper source line DSLb. The intermediate sacrificial layer SCN is a silicon nitride layer or the like which is later replaced with a polysilicon layer or the like to be the intermediate source line BSL.

The plurality of memory holes MH penetrate the stacked bodies LMsb and LMsa, the upper source line DSLb, and the intermediate sacrificial layer SCN and reach the lower source line DSLa. In addition, the above-described slit ST penetrates the stacked bodies LMsb and LMsa and the upper source line DSLb and reaches the intermediate sacrificial layer SCN.

The insulating layer 55s such as the silicon oxide layer is formed on the side wall of the slit ST. The insulating layer 55s has a temporary configuration used as a protective layer of the stacked bodies LMsa and LMsb in the following processing, and is different from the insulating layer 55 described above, which is finally provided in the plate-shaped contact LI.

As shown in FIG. 12B, a removal liquid for the intermediate sacrificial layer SCN, such as hot phosphoric acid, is caused to flow through the slit ST with side wall protected by the insulating layer 55s to remove the intermediate sacrificial layer SCN interposed between the lower source line DSLa and the upper source line DSLb.

Accordingly, the gap layer GPs is formed between the lower source line DSLa and the upper source line DSLb. In addition, a part of the memory layer ME formed at the outer peripheral portion of the memory hole MH is exposed in the gap layer GPs.

At this time, since the side wall of the slit ST is protected by the insulating layer 55s, it is prevented that the insulating layer NL in the stacked bodies LMsa and LMsb is also removed.

As shown in FIG. 12C, the removal liquid for the block insulating layer BK is allowed to flow into the gap layer GPS through the slit ST to remove the block insulating layer BK of the memory layer ME exposed in the gap layer GPs. Accordingly, the block insulating layer BK is removed from a part of the side wall of the memory hole MH, and the inner charge storage layer CT is exposed in the gap layer GPs.

As shown in FIG. 12D, the removal liquid for the charge storage layer CT is allowed to flow into the gap layer GPs through the slit ST to remove the charge storage layer CT exposed in the gap layer GPs. Accordingly, the charge storage layer CT is removed from a part of the side wall of the memory hole MH, and the inner tunnel insulating layer TN is exposed in the gap layer GPs.

As shown in FIG. 12E, the removal liquid for the tunnel insulating layer TN is allowed to flow into the gap layer GPS through the slit ST to remove the tunnel insulating layer TN exposed in the gap layer GPs. Accordingly, the memory layer ME including the tunnel insulating layer TN is removed entirely from a part of the side wall of the memory hole MH in the thickness direction, and the inner channel layer CN is exposed in the gap layer GPs.

As shown in FIG. 12F, a raw material gas such as amorphous silicon is injected from the slit ST with the side wall protected by the insulating layer 55s, and the gap layer GPs is filled with amorphous silicon or the like. In addition, the supporting substrate SS is heat-treated to make the amorphous silicon that fills the gap layer GPs polycrystalline, thereby forming the intermediate source line BSL containing polysilicon or the like.

Accordingly, the pillar PL is formed in which a part of the channel layer CN is connected to the source line SL on the side surface through the intermediate source line BSL.

Next, a state in which the word line WL is formed will be described with reference to FIGS. 13A to 13C. FIGS. 13A to 13C are enlarged sectional views of the pillar PL at a certain height position of the insulating layer NL. That is, FIGS. 13A to 13C are enlarged views of the pillar PL of a portion corresponding to FIGS. 9A to 9E described above.

As shown in FIG. 13A, the insulating layer 55s is removed from the side wall of the slit ST.

As shown in FIG. 13B, a removal liquid for the insulating layer NL, such as hot phosphoric acid, is caused to flow from the slit ST into the stacked bodies LMsa and LMsb to remove the insulating layer NL of the stacked bodies LMsa and LMsb. As a result, a plurality of gap layers GP from which the insulating layer NL between the insulating layers OL is removed are formed.

The stacked bodies LMsa and LMsb including the plurality of gap layers GP have a fragile structure. Such fragile stacked bodies LMsa and LMsb are supported by a plurality of pillars PL. With the support structure of the pillar PL, the remaining insulating layer OL is prevented from being bent, and the stacked bodies LMsa and LMsb themselves are prevented from being distorted or collapsed.

As shown in FIG. 13C, a raw material gas of a conductive material such as tungsten or molybdenum is injected from the slit ST into the plurality of gap layers GP, and the gap layers GP are filled with the conductive material to form a plurality of word lines WL and the like.

As a result, the stacked body LM is formed, which includes stacked bodies LMa and LMb in which a plurality of word lines WL and the like and a plurality of insulating layers OL are alternately stacked one by one.

As described above, the processing of forming the intermediate source line BSL from the intermediate sacrificial layer SCN and the processing of forming the word line WL from the insulating layer NL are also referred to as replacement processing.

The contact CC (refer to FIG. 1) provided in the semiconductor storage device 1 described above is formed as follows. That is, the contact hole reaching each insulating layer NL of the stacked bodies LMsa and LMsb before the word line WL is formed, and the word line WL is formed in the stacked bodies LMa and LMb by the replacement processing, and then the insulating layer is formed on the side wall of the contact hole, and the conductive layer further fills therein, thereby forming the contact CC.

Meanwhile, the formation of the contact hole to the formation of the insulating layer and the filling of the conductive layer may be collectively performed in the stacked bodies LMa and LMb after the replacement processing.

After the processing shown in FIGS. 13A to 13C, the insulating layer 55 is formed on the side wall of the slit ST, and the conductive layer 25 further fills therein to form the plate-shaped contact LI serving as the source line contact. Meanwhile, the insulating layer 55 or the like may fill the slit ST without forming the conductive layer 25 to form a plate-shaped member having no function as a source line contact.

In addition, an insulating layer 53 having a bit line BL is formed on the insulating layer 52, and a plug CH is formed which penetrates the insulating layers 53 and 52 from the height position of the bit line BL and is connected to the cap layer CP of the pillar PL. At this time, a plug connected to the contact CC and an upper layer wiring connected to the plug are also formed. These bit lines BL, upper layer wirings, and the like are electrically connected to an electrode pad formed on the surface of the insulating layer 50 described above.

Meanwhile, the peripheral circuit CBA is formed on the semiconductor substrate SB, which is a separate body from the supporting substrate SS on which the stacked body LM is formed, and is covered with the insulating layer 40. In the insulating layer 40, a contact, a via, wiring, or the like for drawing out the peripheral circuit CBA to the surface of the insulating layer 40 is formed, and the contact, the via, the wiring, or the like is connected to the electrode pad or the like formed on the surface of the insulating layer 40.

In addition, the supporting substrate SS and the semiconductor substrate SB are bonded to each other by the insulating layers 50 and 40 thereof, respectively, and the electrode pads on the surfaces of the insulating layers 50 and 40 are connected to each other. Thereafter, the supporting substrate SS is ground and removed to expose the source line SL, and the electrode film EL is connected through the insulating layer 60 in which the plug PG is formed.

As described above, the semiconductor storage device 1 of the embodiment is manufactured.

### Overview

A semiconductor storage device such as a three-dimensional nonvolatile memory has, for example, a plurality of pillars penetrating a stacked body in which a plurality of word lines are stacked, and memory cells arranged in a height direction are formed in the pillars. These pillars are obtained by forming a multilayer structure such as a channel layer and a memory layer in a memory hole penetrating the stacked body. The plurality of memory holes have a periodic pattern and are disposed at a high density in the memory region.

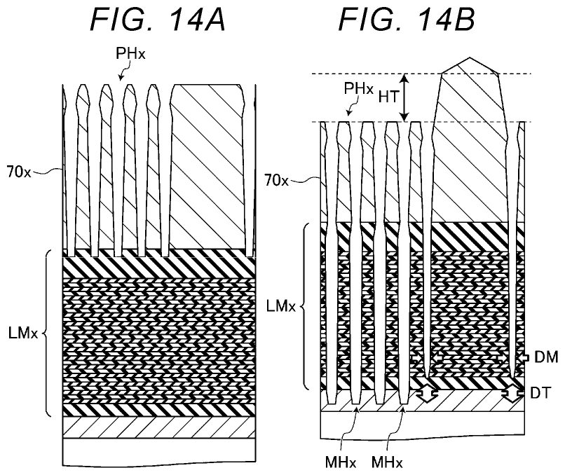

In addition, in order to form a word line by replacing a stacked body formed including a sacrificial layer or the like, a slit for dividing the stacked body in the Y direction is formed in the stacked body. Since the memory hole is not formed in the vicinity of the region where the slit is formed, the periodic disposition of the memory hole is disturbed in the vicinity of the slit. As a result, the processing accuracy of the memory hole in the vicinity of the slit may deteriorate. The state thereof is shown in FIGS. 14A and 14B.

FIGS. 14A and 14B are partially enlarged sectional views showing a state in which a memory hole MHx according to a comparative example is formed.

As shown in FIG. 14A, in the comparative example, a CVD-carbon layer 70x to which a hole pattern PHx of a photoresist layer is transferred is formed on the stacked body LMx. The hole pattern PHx is formed in a periodic pattern in a region excluding a region in which the plate-shaped contact is to be formed later.

As shown in FIG. 14B, a plurality of memory holes MHx penetrating the stacked body LMx are formed using the CVD-carbon layer 70x as a mask. At this time, the CVD-carbon layer 70x is also gradually etched and removed, and the layer thickness of the CVD-carbon layer 70x is reduced. Meanwhile, the amount of reduction in the layer thickness of the CVD-carbon layer 70x may be significantly different between the region where the hole pattern PHx is transferred and the memory hole MHx is formed and the region where the hole pattern PHx is not transferred and the plate-shaped contact is to be formed later.

This is because the volume of the CVD-carbon layer 70x is smaller in the portion where the hole pattern PHx is not transferred than in the portion where the hole pattern PHx is transferred. That is, in a portion to which the hole pattern PHx is transferred and which has a small volume, the etching rate of the CVD-carbon layer 70x is higher than that of a portion to which the hole pattern PHx is not transferred and which has a large volume. Therefore, the amount of reduction in the layer thickness of the CVD-carbon layer 70x is also increased.

As a result, in the region to which the hole pattern PHx is not transferred, the thick CVD-carbon layer 70x is in a state of protruding upward by a predetermined height HT compared to the region to which the hole pattern PHx is transferred. In addition, the protruding CVD-carbon layer 70x inhibits the incidence of ions into the region where the memory hole MHx is formed. Such a phenomenon is also referred to as a shadowing effect. In a case where the incident amount of ions is reduced due to the shadowing effect, the etching rate of the memory hole MHx in that portion is reduced, or the memory hole MHx is not sufficiently opened.

As a result, in a portion adjacent in the Y direction to the region in which the plate-shaped contact is to be formed later, the etching depth DT of the memory hole MHx may be insufficient compared to the other memory holes MHx, or the processing dimension DM of the memory hole MHx may be reduced.

According to the method for manufacturing the semiconductor storage device 1 of the embodiment, in a case where the plurality of memory holes MHb are formed, the plurality of hole patterns PHb and PDb are provided, which are dispersedly disposed over the entire region including the position where the plate-shaped contact LI is to be formed later, and the CVD-carbon layer 74 that covers the stacked body LMsb is formed.

As a result, the volume difference of the CVD-carbon layer 74 between the formation region of the memory hole MHb and the formation region of the plate-shaped contact LI can be reduced, and the layer thickness difference of the CVD-carbon layer 70x between these regions can be reduced during the formation of the memory hole MHb. Therefore, the etching depth and the processing dimension of the memory hole MHb adjacent to the formation region of the plate-shaped contact LI can be matched with those of the other memory holes MHb by preventing the shadowing effect, and the memory hole MHb having a desired etching depth and processing dimension can be formed.

As described above, with the above configuration, it is possible to improve the processing accuracy of the memory hole MHb adjacent to the formation region of the plate-shaped contact LI.

According to the method for manufacturing the semiconductor storage device 1 of the embodiment, the plurality of memory holes MHb are formed in the region which is to be the memory region MR later, while the stacked body LMsb in the formation region of the plate-shaped contact LI is protected by the stopper layer SPb, through the CVD-carbon layer 74. As a result, the hole pattern PDb is prevented from being transferred to the stacked body LMsb.

According to the method for manufacturing the semiconductor storage device 1 of the embodiment, the CVD-carbon layer 74 has a plurality of hole patterns PHb, which are disposed at a predetermined pitch in a region which is to be the memory region MR later, and a plurality of hole patterns PDb, which are disposed at a predetermined pitch in a region in which the plate-shaped contact LI is to be formed later and respectively have a smaller opening area than the plurality of hole patterns PHb. As a result, the transfer of the hole pattern PHb to the stacked body LMsb can be further prevented in the region in which the plate-shaped contact LI is to be formed later.

According to the method for manufacturing the semiconductor storage device 1 of the embodiment, the slit ST is formed to extend in the direction along the X direction in a region between the stopper layer SPb, which continuously extends in the direction along the X direction, and a stopper layer SPb, which continuously extends in the direction along the X direction at a position separated from the stopper layer SPb in the Y direction by a predetermined distance.

Accordingly, the width of the slit ST widened in the Y direction can be narrowed again due to the retreat of the CVD-carbon layer 74. Therefore, the slit ST can be formed to have a desired dimension.

According to the method for manufacturing the semiconductor storage device 1 of the embodiment, the semiconductor storage device 1 including the stopper layer SPb, which is disposed adjacent to the plate-shaped contact LI in the Y direction, has the upper end portion at the height position of the upper end portions of the plurality of pillars PL, and has the lower end portion above word line WL of the uppermost layer among the plurality of word lines WL of the stacked body LM, is obtained.

In the above-described embodiment, the hole patterns PDa and PDb transferred to the CVD-carbon layers 72 and 74, respectively, have substantially the same pitch as the hole patterns PHa and PHb for forming the memory holes MHa and MHb, for example. Meanwhile, as long as the shadowing effect can be prevented, the hole patterns PDa and PDb may have a pitch larger than that of the hole patterns PHa and PHb, for example. As an example, by increasing the pitches of the hole patterns PDa and PDb, the disposition densities of the hole patterns PDa and PDb can be set to 50% or more with respect to the disposition densities of the hole patterns PHa and PHb, respectively.

By relatively increasing the pitches of the hole patterns PDa and PDb, the hole patterns PDa and PDb are further prevented from being transferred to the stacked bodies LMsa and LMsb.

Meanwhile, a configuration may be adopted in which the hole patterns PDa and PDb and the hole patterns PHa and PHb are set to have substantially the same pitch, and the diameters and the opening areas of the hole patterns PDa, PDb, PHa, and PHb are set to be substantially the same, so that the shadowing effect can be further prevented.

In addition, in the above-described embodiment, it is assumed that the stopper layers SPa and SPb remain in the finally obtained semiconductor storage device 1. Meanwhile, the stopper layers SPa and SPb are dummy configurations that do not contribute to the function of the semiconductor storage device 1. Therefore, after the memory holes MHa and MHb are formed, at least any one of the stopper layers SPa and SPb may be removed.

### Modification Example

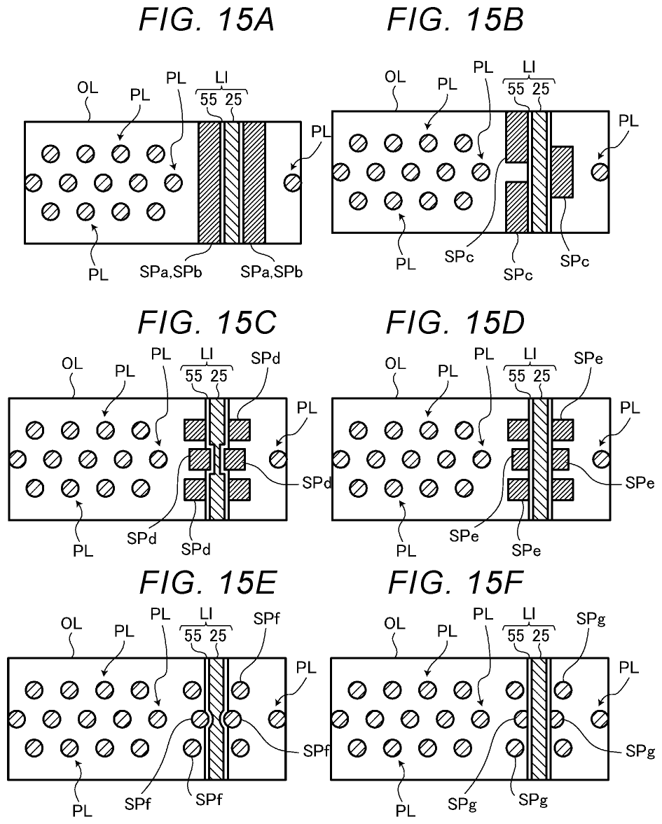

Next, a semiconductor storage device of a modification example according to the embodiment will be described with reference to FIGS. 15A to 15F.

In the above-described embodiment, the semiconductor storage device 1 includes a plurality of stopper layers SPa and SPb that are adjacent to both sides of the plate-shaped contact LI in the Y direction and that extend in the direction along the plate-shaped contact LI along the X direction. However, the configuration of the stopper layer is not limited thereto.

FIGS. 15A to 15F are XY sectional views showing examples of various stopper layers SPa to SPg provided in the semiconductor storage device according to the embodiment and the modification example of the embodiment. More specifically, FIGS. 15A to 15F show an XY cross section at the height position of the uppermost insulating layer OL of the stacked body LMa or the stacked body LMb.

In addition, in FIGS. 15A to 15F, the same symbol is attached to the same configuration as that in the embodiment, and the description may be omitted.

As shown in FIG. 15A, the stopper layers SPa and SPb may be adjacent to the plate-shaped contact LI on both sides in the Y direction and may continuously extend in the direction along the plate-shaped contact LI along the X direction, as described in the embodiment described above.

Meanwhile, the stopper layer does not need to continuously extend, and it is sufficient that at least the region overlapping the hole patterns PDa and PDb, which are formed at a predetermined pitch, in the up-down direction can be protected.

As shown in FIG. 15B, the stopper layer SPc may be adjacent to the plate-shaped contact LI on both sides in the Y direction and may intermittently extend in the direction along the plate-shaped contact LI along the X direction.

As shown in FIG. 15C, the stopper layer SPd may be formed in a pad shape at a position overlapping the above-described hole patterns PDa and PDb. In this case, it is preferable that each of the stopper layers SPd has an area larger than the opening area of the hole patterns PDa and PDb.

In addition, in the above case, the stopper layers SPd are disposed on both sides of the plate-shaped contact LI in the Y direction at distances different from the plate-shaped contact LI. Therefore, the distance between the stopper layers SPd facing each other on both sides in the Y direction with the plate-shaped contact LI interposed therebetween may change depending on the position in the X direction. Therefore, the width of the plate-shaped contact LI in the Y direction may also be different depending on the position in the X direction.

Meanwhile, in order to prevent the width of the plate-shaped contact LI in the Y direction from changing depending on the position in the X direction, at least a part of the stopper layer SPd may be removed after the formation of the memory holes MHa and MHb.

FIG. 15D shows an example of the stopper layer SPe in which the portion overlapping the formation position of the slit ST in the stacking direction is removed after the formation of the memory holes MHa and MHb. In the example of FIG. 15D, a part of the pair of stopper layers SPe at the central portion in the up-down direction of the paper surface, which are disposed at a relatively short distance on both sides in the Y LI interposed direction with the plate-shaped contact therebetween, is removed, and the area is smaller than the stopper layers SPe at both end portions in the up-down direction of the paper surface.

Accordingly, a change in the width of the plate-shaped contact LI in the Y direction depending on the position in the X direction is prevented.

As shown in FIG. 15E, the stopper layer SPf may be formed in a circular shape in accordance with the shapes of the hole patterns PDa and PDb at a position overlapping the above-described hole patterns PDa and PDb. Even in this case, it is preferable that each of the stopper layers SPf has an area larger than the opening area of the hole patterns PDa and PDb.

In addition, in the above case, the distance between the stopper layers SPf facing each other on both sides in the Y direction with the plate-shaped contact LI interposed therebetween may also change depending on the position in the X direction, and the width of the plate-shaped contact LI in the Y direction may also be different depending on the position in the X direction.

Meanwhile, in order to prevent the width of the plate-shaped contact LI in the Y direction from changing depending on the position in the X direction, at least a part of the stopper layer SPf may be removed after the formation of the memory holes MHa and MHb.

FIG. 15F shows an example of the stopper layer SPg in which the portion overlapping the formation position of the slit ST in the stacking direction is removed after the formation of the memory holes MHa and MHb. In the example of FIG. 15F, a part of the pair of stopper layers SPg at the central portion in the up-down direction of the paper surface, which are disposed at a relatively short distance on both sides in the Y direction with the plate-shaped contact LI interposed therebetween, is removed, and the area is smaller than the stopper layers SPg at both end portions in the up-down direction of the paper surface.

Accordingly, a change in the width of the plate-shaped contact LI in the Y direction depending on the position in the X direction is prevented.

According to the semiconductor storage device of the modification example, the same effects as those of the semiconductor storage device 1 of the above-described embodiment are obtained.

### Other Modification Examples

In the above-described embodiment and modification example, the contact region ER and the like are disposed at both end portions of the stacked body LM in the X direction. However, the disposition position of the contact region in the stacked body LM is not limited thereto. The contact region may be disposed, for example, at the central portion of the stacked body LM, and in this case, for example, the memory region can be disposed at both end portions of the stacked body.

In addition, in the above-described embodiment and modification example, the pillar PL is connected to the source line SL on the side surface of the channel layer CN, but the present disclosure is not limited thereto. For example, the pillar may be configured such that the memory layer on the bottom surface of the pillar is removed and the pillar connects to the source line at the lower end portion of the channel layer.

In addition, in the above-described embodiment and modification example, the insulating layers NL and OL are stacked in twice to form the stacked body LM having the 2-tier structure including the stacked bodies LMa and LMb. However, the stacked body may have a 1-tier structure or may have a 3-tier or more structure. By increasing the number of tiers, the number of stacked layers of the word line WL can be further increased.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a stacked body including a plurality of conductive layers and a plurality of insulating layers alternately stacked on top of one another in a stacking direction;
a first region extending in a first direction intersecting the stacking direction and has a width in a second direction intersecting the stacking direction and the first direction;
a plurality of first pillars disposed in a second region on a first side of the first region in the second direction, and each extending in the stacked body, wherein first memory cells are formed at intersections between the plurality of conductive layers and the plurality of first pillars, respectively;
a plurality of second pillars disposed in a third region on a second side of the first region in the second direction, and each extending in the stacked body, and wherein second memory cells are formed at intersections between the plurality of conductive layers and the plurality of second pillars, respectively;
a plate-shaped portion disposed in the first region, extending in the first direction, and dividing the stacked body in the second direction; and
a semiconductor layer disposed in the first region adjacent to the plate-shaped portion in the second direction, the semiconductor layer having an upper end portion around upper end portions of the plurality of first and second pillars, and a lower end portion above an uppermost conductive layer of the plurality of conductive layers.

2. The semiconductor storage device according to claim 1,
wherein the semiconductor layer is disposed on both sides of the plate-shaped portion in the second lateral direction.

3. The semiconductor storage device according to claim 2,
wherein a width of the plate-shaped portion in the second lateral direction is narrower than a width of an upper end portion of the plate-shaped portion at a height position of the semiconductor layer.

4. The semiconductor storage device according to claim 1,
wherein the semiconductor layer continuously extends in the first lateral direction along the plate-shaped portion.

5. The semiconductor storage device according to claim 1,
wherein the semiconductor layer intermittently extends in the first lateral direction along the plate-shaped portion.

6. A semiconductor storage device comprising:
a first stacked body including a plurality of first conductive layers and a plurality of first insulating layers alternately stacked on top of one another in a stacking direction;
a second stacked body disposed above the first stacked body, and including a plurality of second conductive layers and a plurality of second insulating layers alternately stacked on top of one another in the stacking direction;
a first region that extends in a first direction intersecting the stacking direction and has a width in a second direction intersecting the stacking direction and the first direction;
a plurality of first pillars disposed in a second region on a first side of the first region in the second direction, and each extending in the first and second stacked bodies, wherein first memory cells are formed at intersections between the plurality of first and second conductive layers and the plurality of first pillars, respectively;
a plurality of second pillars disposed in a third region on a second side of the first region in the second direction, and each extending in the first and second stacked bodies, wherein second memory cells are formed at intersections between the plurality of first and second conductive layers and the plurality of second pillars, respectively;
a plate-shaped portion disposed in the first region, extending in the first direction, and dividing the first and second stacked bodies in the second direction;
a first semiconductor layer disposed in the first region adjacent to the plate-shaped portion in the second direction and in an uppermost first insulating layer among the plurality of first insulating layers; and
a second semiconductor layer disposed in the first region adjacent to the plate-shaped portion in the second direction and in an uppermost second insulating layer of the plurality of second insulating layers.

7. A method for manufacturing a semiconductor storage device, the method comprising:
forming a stacked body including a plurality of first insulating layers and a plurality of second insulating layers alternately stacked on top of one another in a stacking direction;
forming a semiconductor layer over an uppermost second insulating layer of the plurality of second insulating layers, wherein the semiconductor layer is disposed in a first region extending in a first lateral direction intersecting the stacking direction and has a predetermined width in a second direction; and
forming a plurality of first memory holes disposed in a second region on a first side of the first region in the second direction and extending in the stacked body; and
forming a plurality of second memory holes disposed in a third region on a second side of the first region in the second direction and extending in the stacked body,
wherein when forming the first and second memory holes, the method further comprises:
forming a mask pattern with a plurality of hole patterns over the first to third regions, the plurality of first and second memory holes being formed in the second and third regions through the mask pattern, respectively, while the semiconductor layer protecting the stacked body in the first region.

8. The method for manufacturing a semiconductor storage device according to claim 7,
wherein the plurality of hole patterns include
a plurality of first hole patterns disposed in the second and third regions with a first period, and
a plurality of second hole patterns disposed in the first region with a second period and each having a smaller opening area than the plurality of first hole patterns.

9. The method for manufacturing a semiconductor storage device according to claim 8,
wherein the first period and the second period are equal to each other.

10. The method for manufacturing a semiconductor storage device according to claim 7, after forming the first and second memory holes, further comprising:
forming a slit in the first region, the slit extending in the first lateral direction and dividing the stacked body in the second direction.

11. The semiconductor storage device according to claim 1, further comprising a conductive layer filling the plate-shaped portion.

12. The semiconductor storage device according to claim 6, further comprising a conductive layer filling the plate-shaped portion.
